(19) United States
(12) Patent Application Publication
(10) Pub. No.: US 2021/0227711 A1
(43) Pub. Date: Jul. 22, 2021

(54) CONNECTOR

(71) Applicant: JAPAN AVIATION ELECTRONICS INDUSTRY, LIMITED, Tokyo (JP)

(72) Inventor: Tomohiro NAKAMURA, Tokyo (JP)

(73) Assignee: JAPAN AVIATION ELECTRONICS INDUSTRY, LIMITED, Tokyo (JP)

(21) Appl. No.: 17/108,359

(22) Filed: Dec. 1, 2020

(30) Foreign Application Priority Data
Jan. 21, 2020 (JP) 2020-007234

(51) Int. Cl. H05K 5/02; H01L 23/40

(52) U.S. Cl. CPC H05K 5/0286; H05K 7/205; H05K 5/0269; H01L 23/4093

(57) ABSTRACT

A connector is provided with a base, a terminal, a cover and a heat conductive member. The base has a holding portion, and the terminal is held by the holding portion. The cover is provided with a main portion having an inner surface and an outer surface. The heat conductive member is fixed on the inner surface. When the connector is connected to a card-type device, the terminal pushes a card-type device against the heat conductive member in a predetermined direction perpendicular to a circuit board. When the connector is connected to the card-type device, an interval between the main portion and the holding portion is kept constant in the predetermined direction.

### CROSS REFERENCE TO RELATED APPLICATIONS

This application is based on and claims priority under 35 U.S.C. § 119 to Japanese Patent Application No. JP2020-007234 filed Jan. 21, 2020, the contents of which are incorporated herein in their entirety by reference.

### BACKGROUND OF THE INVENTION

This invention relates to a connector, particularly to a connector which is connectable to a card-type device.

JP2015-153992A (Patent Document 1) discloses an electronic device which accommodates a connector module (a card-type device). As shown in FIG. 21, an electronic device 90 of Patent Document 1 is provided with a case body (a base) 92, a radiator portion (a cover) 94 attached to the case body 92 so as to be openable and closeable and a heat conductive sheet (a heat conductive member) 96 attached to the radiator portion 94.

As understood from FIG. 21, upon accommodating a connector module 98 in the case body 92, a push portion 980 of the connector module 98 pushes an end portion 940 of the radiator portion 94. When the end portion 940 is pushed by the connector module 98, the radiator portion 94 pivots on a central axis 942. Accordingly, the heat conductive sheet 96 attached to the radiator portion 94 comes into contact with a principal surface 982 of the connector module 98. As a result, heat generated in the connector module 98 is conducted to the radiator 94 via the heat conductive sheet 96.

### SUMMARY OF THE INVENTION

The electronic device 90 disclosed in Patent Document 1 uses the principle of leverage, which uses the central axis 942 as a fulcrum, so that a small linear motion of the connector module 98 is changed into a large pivoting motion of the radiator 94. Accordingly, it is difficult to increase a contact pressure between the heat conductive sheet 96 and the principle surface 982 of the connector module 98. Therefore, the electronic device 90 disclosed in Patent Document 1 has a probability that it is difficult to conduct heat from the connector module 98 to the heat conductive sheet 96 due to insufficient contact pressure between the heat conductive sheet 96 and the connector module 98.

It is therefore an object of the present invention to provide a connector which is connectable to a card-type device and which is provided with a heat conductive member and capable of producing high contact pressure between the heat conductive member and the card-type device.

One aspect of the present invention provides a connector connectable to a card-type device. The connector is mounted on a circuit board when used. The connector comprises a base, a terminal, a cover and a heat conductive member. The base has a holding portion. The terminal is held by the holding portion. The cover comprises a main portion having an inner surface and an outer surface. The heat conductive member is fixed on the inner surface. When the connector is connected to the card-type device, the terminal pushes the card-type device against the heat conductive member in a predetermined direction perpendicular to the circuit board. When the connector is connected to the card-type device, an interval between the main portion and the holding portion is kept constant in the predetermined direction.

In the connector, the heat conductive member is fixed on the inner surface of the main portion of the cover, and the terminal is held by the holding portion of the base. When the card-type device is connected to the connector, the terminal pushes the card-type device against the heat conductive member in the predetermined direction. Meanwhile, an interval between the main portion of the cover and the holding portion is kept constant in the predetermined direction. Accordingly, a pushing force with which the terminal pushes the card-type device becomes entirely contact pressure between the card-type device and the heat conductive member. In this manner, it is possible to generate high contact pressure between the heat conductive member and the card-type device.

An appreciation of the objectives of the present invention and a more complete understanding of its structure may be had by studying the following description of the preferred embodiment and by referring to the accompanying drawings.

### BRIEF DESCRIPTION OF THE DRAWINGS

FIG. 1 is a first perspective view showing a connector according to a first embodiment of the present invention. A cover of the connector is positioned in an open position.

FIG. 2 is a second perspective view showing the connector of FIG. 1. The cover of the connector is positioned in a push-down position.

FIG. 3 is a third perspective view showing the connector of FIG. 1. The cover of the connector is positioned in a locked position.

FIG. 4 is a fourth perspective view showing the connector of FIG. 1. The cover of the connector is positioned in the open position and holds a card-type device.

FIG. 5 is a fifth perspective view showing the connector of FIG. 1. The cover of the connector is positioned in the push-down position and holds the card-type device. The card-type device is accommodated in an accommodation portion of a base of the connector.

FIG. 6 is a sixth perspective view showing the connector of FIG. 1. The cover of the connector is positioned in the locked position and holds the card-type device. The card-type device is accommodated in the accommodation portion of the base of the connector.

FIG. 7 is a plane view showing the connector of FIG. 3.

FIG. 8 is a cross-sectional view showing the connector of FIG. 7, taken along line A-A.

FIG. 9 is a plane view showing the connector of FIG. 6.

FIG. 10 is a cross-sectional view showing the connector of FIG. 9, taken along line B-B.

FIG. 11 is a partial, enlarged, cross-sectional view showing a heat conductive member included in the connector of FIG. 8 or 10.

FIG. 12 is a partial, enlarged, cross-sectional view showing a modified example of the heat conductive member of FIG. 11.

FIG. 13 is a perspective view showing a connector according to a second embodiment of the present invention.

FIG. 14 is an exploded, top, perspective view showing the connector of FIG. 13.

FIG. 15 is an exploded, bottom, perspective view showing the connector of FIG. 13.

FIG. 16 is another perspective view showing the connector of FIG. 13. To the connector, a card-type device is connected.

FIG. 17 is a plane view showing the connector of FIG. 13.

FIG. 18 is a cross-sectional view showing the connector of FIG. 17, taken along line C-C.

FIG. 19 is a plane view showing the connector of FIG. 16.

FIG. 20 is a cross-sectional view showing the connector of FIG. 19, taken along line D-D.

FIG. 21 is a cross-sectional view showing an electronic device disclosed in Patent Document 1. Into the electronic device, a connector module is halfway inserted.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DESCRIPTION OF PREFERRED EMBODIMENTS

### First Embodiment

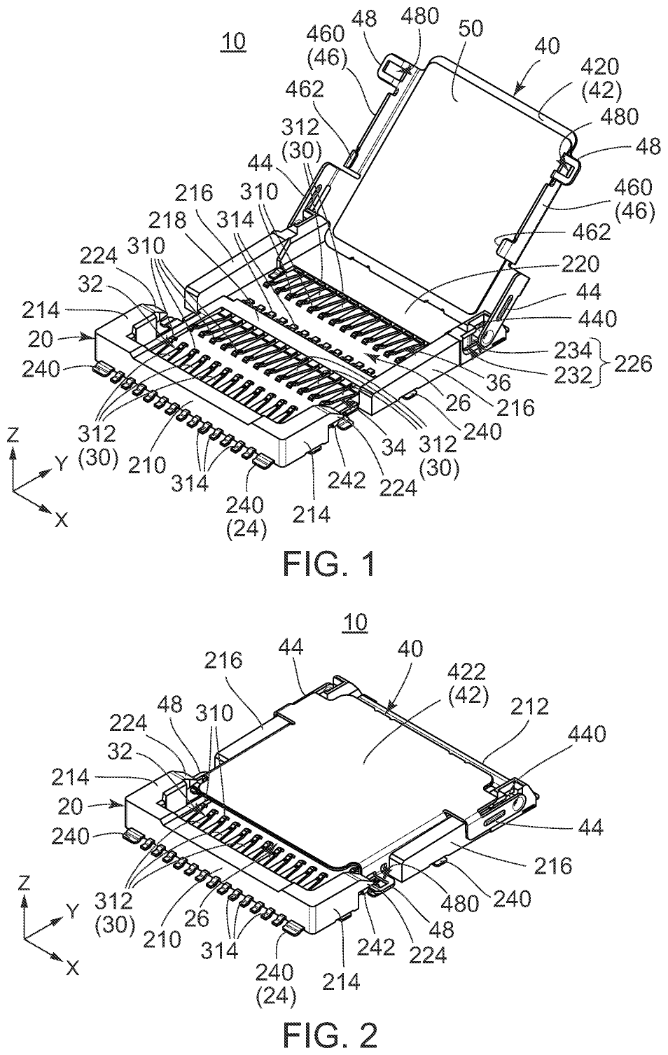

Referring to FIG. 1, a connector 10 according to a first embodiment of the present invention is provided with a base 20, a plurality of terminals 30, a cover 40 and a heat conductive member 50.

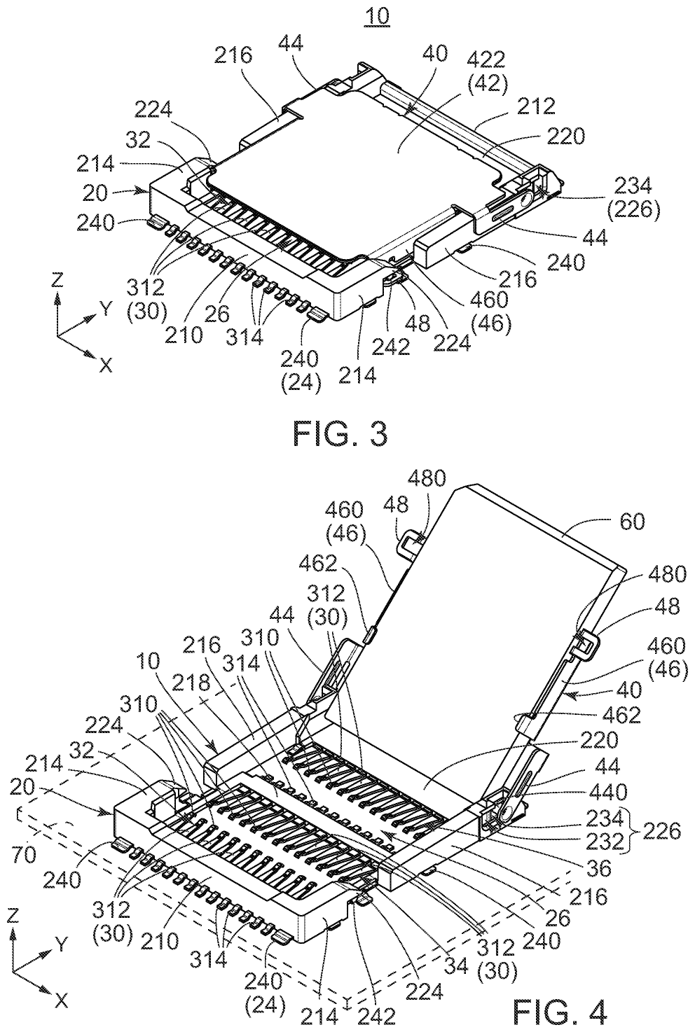

As understood from FIGS. 1 and 2, the cover 40 is attached to the base 20 so as to be openable and closeable with respect to the base 20. In other words, the cover 40 can shift between an open state shown in FIG. 1 and a push-down state shown in FIG. 2. Moreover, as understood from FIGS. 2 and 3, the cover 40 is attached to the base 20 so as to be movable in a front-rear direction with respect to the base 20. In other words, the cover 40 can shift between the push-down state shown in FIG. 2 and a locked state shown in FIG. 3. In the present embodiment, the front-rear direction is a Y-direction. A negative Y-direction is directed forward while a positive Y-direction is directed rearward.

As understood from FIG. 4, the connector 10 is mounted on a circuit board 70 when used. As understood from FIGS. 4 to 6, the connector 10 is connected to a card-type device 60. The card-type device 60 has a flat, rectangular parallelepiped shape with a pair of principle surfaces. Here, the card-type device 60 means not only a device alone but also a combination of a device and accessories, such as a tray.

As shown in FIGS. 1 to 3, the base 20 has a front wall 210, a rear wall 212, a pair of front sidewalls 214, a pair of rear sidewalls 216, a middle bottom board 218 and a rear bottom board 220. The front wall 210, the rear wall 212, the front sidewalls 214, the rear sidewalls 216, the middle bottom board 218 and the rear bottom board 220 are made of insulation resin and molded integrally with a frame 24. Parts of the frame 24 are exposed outside to form fixed portions 240 and locking portions 242.

As shown in FIG. 1, the front wall 210 is located at a front end of the base 20 and extends in a lateral direction. The front sidewalls 214 extend rearward from both ends of the front wall 210 in the lateral direction, respectively. Each of the front sidewalls 214 has an overhanging portion 224 projecting rearward. The locking portions 242 protrude from lower surfaces of the overhanging portions 224, respectively. In the present embodiment, the lateral direction is an X-direction.

As shown in FIG. 1, the rear sidewalls 216 are located rearward of and apart from the front sidewalls 214, respectively. Each of the rear sidewalls 216 extends in the front-rear direction. Each of the rear sidewalls 216 is formed with a bearing portion 226. The bearing portion 226 is a recess portion recessed inward in the lateral direction. The bearing portion 226 has a front portion 232 and a rear portion 234.

As shown in FIG. 3, the rear wall 212 is located at a rear end of the base 20. The rear wall 212 extends in the lateral direction and couples rear ends of the rear sidewalls 216 with each other. A size of the rear wall 212 in an up-down direction is smaller than that of the rear sidewalls 216 in the up-down direction. In addition, a size of the rear wall 212 in the front-rear direction is smaller than that of the front wall 210 in the front-rear direction. In the present embodiment, the up-down direction is a Z-direction. A positive Z-direction is directed upward while a negative Z-direction is directed downward.

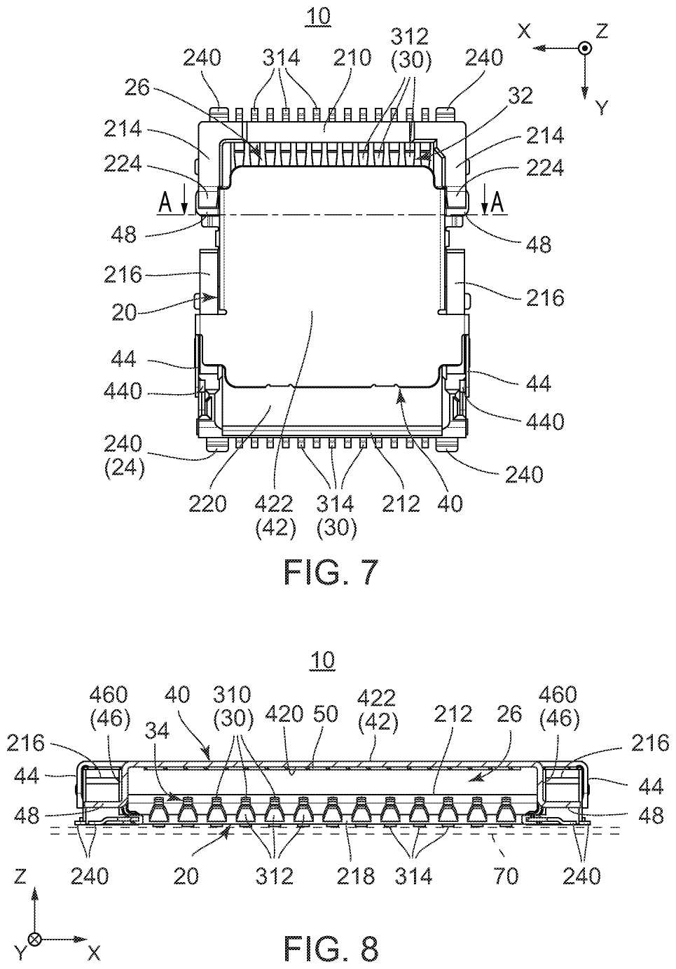

As shown in FIG. 1, the middle bottom board 218 extends in the lateral direction and couples the vicinities of front ends of the rear sidewalls 216 with each other. The rear bottom board 220 extends in the lateral direction and couples the rear ends of the rear sidewalls 216 with each other. As understood from FIGS. 3 and 7, the rear wall 212 is formed integrally with the rear bottom board 220 along a rear edge of the rear bottom board 220. The rear wall 212 protrudes upward from the rear bottom board 220.

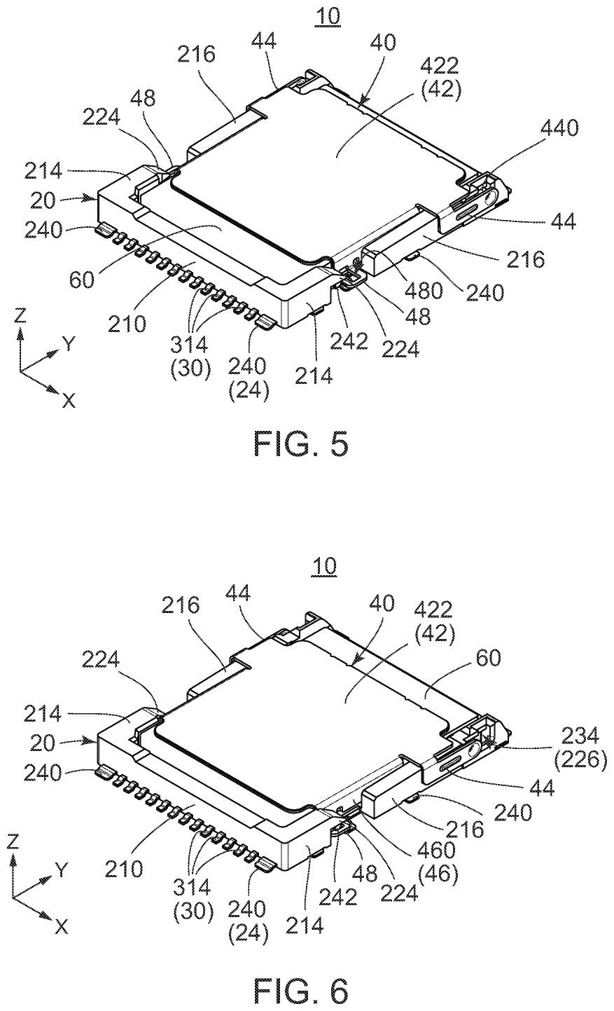

As understood from FIG. 1, the front wall 210, the rear wall 212, the pair of the front sidewalls 214, the pair of the rear sidewalls 216, the middle bottom board 218 and the rear bottom board 220 define an accommodation portion 26 having an approximately flat, rectangular parallelepiped shape. As understood from FIGS. 5 and 6, the accommodation portion 26 can accommodate the card-type device 60. In other words, the base 20 is provided with the accommodation portion 26 for accommodating the card-type device 60.

As shown in FIG. 1, the terminals 30 are held by the base 20. In the present embodiment, the terminals 30 are arranged in three rows and held by the base 20. Moreover, in the present embodiment, the number of the terminals 30 is thirteen in each row. However, the present invention is not limited thereto. The number and arrangement of the terminals 30 can be designed freely. However, it is desirable that the terminals 30 are arranged so that points of action of forces applied from the terminals 30 on the card-type device 60 are two-dimensionally distributed and the forces are balanced when the connector 10 is connected to the card-type device 60.

As shown in FIG. 1, the terminals 30 of a first terminal row 32 are held by the front wall 210. The terminals 30 of a second terminal row 34 are held by the middle bottom board 218. The terminals 30 of a third terminal row 36 are held by the rear bottom board 220. Thus, the front wall 210, the middle bottom board 218 and the rear bottom board 220 function as holding portions 210, 218 and 220, respectively, which hold the terminals 30. In other words, in the present embodiment, the base 20 has the holding portions 210, 218 and 220, and the terminals 30 are held by the holding portions 210, 218 and 220. Each of the terminals 30 has a held portion which is held by the holding portion 210, 218 or 220.

As understood from FIG. 1, the terminals 30 of the first terminal row 32, the terminals 30 of the second terminal row 34 and the terminals 30 of the third terminal row 36 have the same basic structure as one another. In the present embodiment, there are some differences among the terminals 30 of the first terminal row 32, the terminals 30 of the second terminal row 34 and the terminals 30 of the third terminal row 36 in size of each part. However, the present invention is not limited thereto. The terminals 30 of the first terminal row 32, the terminals 30 of the second terminal row 34 and the terminals 30 of the third terminal row 36 may be formed to be identical with one another.

As understood from FIG. 1, each of the terminals 30 has a contact point 310, a supporting portion 312 and a fixed portion 314 along with the held portion. Each of the terminals 30 is formed of a single metal plate, and the supporting portion 312, the held portion (not shown) and the fixed portion 314 are continuous in this order. The supporting portion 312 protrudes forward or rearward from the holding portion 210, 218 or 220 of the base 20 and extends diagonally upward like a cantilever. The contact point 310 is located at the vicinity of a tip of the supporting portion 312. The supporting portion 312 is resiliently deformable and supports the contact point 310 to be movable at least in the up-down direction. As understood from FIGS. 7 and 8, the supporting portion 312 supports the contact point 310 so that the contact point 310 is in the accommodation portion 26.

As shown in FIG. 1, the fixed portion 314 of the terminal 30 protrudes from the holding portion 210, 218 or 220 of the base 20 in an opposite direction opposite to the supporting portion 312 of the terminal 30 in the front-rear direction. The fixed portion 314 extends forward or rearward from the held portion (not shown), then downward, and further forward or rearward. As understood from FIG. 4, when the connector 10 is mounted on the circuit board 70, the fixed portions 314 of the terminals 30 are connected and fixed to pads on the circuit board 70 which correspond to them, respectively. In addition, the fixed portions 240 of the frame 24 are fixed to fixing portions (not shown) on the circuit board 70 which correspond to them, respectively.

As shown in FIGS. 1 and 2, the cover 40 is provided with a main portion 42, a pair of axis-supporting portions 44, a pair of card-holding portions 46 and a pair of locked portions 48. The cover 40 is formed of a single metal plate. The main portion 42 is approximately rectangular thin plate-like and has an inner surface 420 directed in a first direction perpendicular to the main portion 42 and an outer surface 422 directed in an opposite direction opposite to the first direction. In the locked state shown in FIG. 3, the first direction is a direction directed downward. Accordingly, in the locked state shown in FIG. 3, the inner surface 420 is a surface directed downward, and the outer surface 422 is a surface directed upward.

As shown in FIG. 1, the axis-supporting portions 44 are provided on both edges of the main portion 42 in the lateral direction. In a second direction perpendicular to both of the lateral direction and the first direction, the axis-supporting portions 44 are located in the vicinity of one of end portions of the main portion 42. In the locked state shown in FIG. 3, the second direction coincides with the front-rear direction.

As understood from FIG. 1, each of the axis-supporting portions 44 has an axis portion 440. The axis portion 440 is a protrusion protruding inward in the lateral direction. The axis portions 440 are located at one of end portions of the cover 40 in the second direction. The axis portions 440 are respectively received by the bearing portions 226 of the rear sidewalls 216 of the base 20. The axis portions 440 and the bearing portions 226 form a hinge mechanism. With this hinge mechanism, the cover 40 is pivotable with respect to the base 20. Within a range in which the bearing portions 226 allow the axis portions 440 to move, the cover 40 is movable with respect to the base 20 in the front-rear direction. In detail, the axis portions 440 are movable between the front portions 232 of the bearing portions 226 and the rear portions 234 of the bearing portions 226.

As shown in FIG. 1, the card-holding portions 46 are provided at both edges of the main portion 42 in the lateral direction. In the locked state shown in FIG. 3, the card-holding portions 46 are located forward of the axis-supporting portions 44 in the front-rear direction. Each of the card-holding portions 46 has a guide portion 460 and a hook portion 462. The guide portions 460 protrude in the first direction from the main portion 42 and extend in the second direction. Each of the hook portions 462 protrudes inward in the lateral direction from one of end portions of the guide portion 460 corresponding thereto. The hook portions 462 are located in the vicinity of the middle of the cover 40 in the second direction.

As understood from FIG. 4, the card-holding portions 46 can loosely hold the card-type device 60. The card-holding portions 46 hold the card-type device 60 so that the principle surfaces of the card-type device 60 are parallel to the main portion 42 of the cover 40. The card-holding portions 46 regulate movement of the card-type device 60 in the lateral direction. Moreover, the card-holding portions 46 regulate movement of the card-type device 60 in the first direction. However, the card-holding portions 46 allow the card-type device 60 to be moved in the second direction. In other words, the card-type device 60 can be inserted into and removed from the cover 40 in the second direction. Thus, in a state before the connector 10 is connected to the card-type device 60, the card-type device 60 is movable with respect to the cover 40. The guide portions 460 of the card-holding portions 46 guide movement of the card-type device 60 in the second direction.

As shown in FIG. 1, each of the locked portions 48 protrudes outward in the lateral direction from the other of the end portions of the guide portion 460 of the card-holding portions 46 corresponding thereto. Each of the locked portions 48 is provided with an opening portion 480. As understood from FIGS. 1 and 2, the locked portion 48 has a size which can pass through between the front sidewall 214 and the rear sidewall 216. Accordingly, the locked portion 48 can be positioned downward of the overhanging portion 224 of the front sidewall 214 in the up-down direction. Moreover, in the locked state shown in FIG. 3, the locked portions 48 engage with the locking portions 242, respectively. In detail, in the locked state, the locking portions 242 are respectively inserted into the opening portions 480 of the locked portions 48 at least in part and regulate rearward movement of the cover 40 with respect to the base 20.

As shown in FIG. 1, the heat conductive member 50 is fixed on the inner surface 420 of the main portion 42 of the cover 40. In the present embodiment, the heat conductive member 50 is stuck on the inner surface 420 of the main portion 42 of the cover 40. The heat conductive member 50 covers approximately the whole of the inner surface 420 of the main portion 42 of the cover 40. In the present embodiment, the heat conductive member 50 is a thin rectangular sheet formed of a flexible material. A thickness of the heat conductive member 50 is about 0.1 mm, for example.

As understood from FIGS. 1 and 4, when the card-type device 60 is held by the cover 40, the heat conductive member 50 faces one of the principle surfaces of the card-type device 60 (a first principle surface). In order to increase an area facing the card-type device 60, it is desirable that a size of the heat conductive member 50 is larger in the lateral direction and in the second direction.

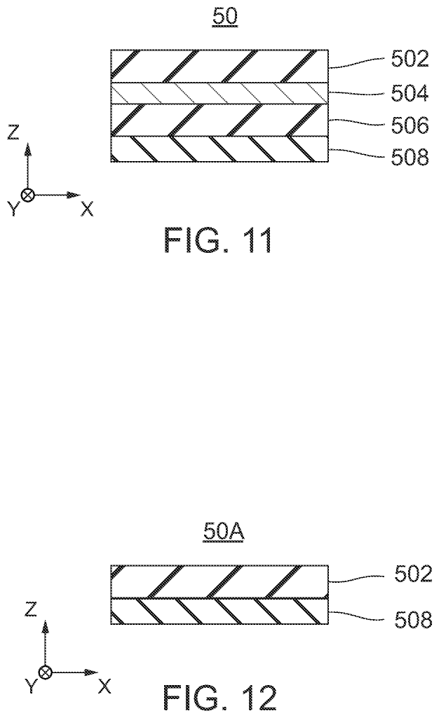

As shown in FIG. 11, in the present embodiment, the heat conductive member 50 is provided with a first heat conductive acrylic adhesive layer 502, a metal layer 504, a second heat conductive acrylic adhesive layer 506 and a covering layer 508. As the metal layer 504, a copper foil or an aluminum foil may be used. However, the present invention is not limited thereto. Although the metal layer 504 is effective at accelerating heat conduction in surface direction, it is not essential. Accordingly, as a substitute for the heat conductive member 50, a heat conductive member 50A shown in FIG. 12 may be used. The heat conductive member 50A shown in FIG. 12 is formed of a first heat conductive acrylic adhesive layer 502 and a covering layer 508. The heat conductive member 50A is simple in structure in comparison with the heat conductive member 50 and possible to reduce a cost and to decrease a thickness thereof. In any case, the first heat conductive acrylic adhesive layer 502 is a layer to be stuck on the inner surface 420 of the main portion 42 of the cover 40. Moreover, the covering layer 508 is a layer facing the card-type device 60 when the connector 10 is connected to the card-type device 60. The covering layer 508 is made of insulating material. It is preferable to use material having small coefficient of friction for the covering layer 508 to reduce a coefficient of friction against the card-type device 60. As the covering layer 508, a polyimide film may be used, for example.

As understood from FIGS. 4 and 5, upon turning the cover 40 in a closing direction in a state that the card-type device 60 is held by the cover 40, the card-type device 60 is accommodated in the accommodation portion 26 of the base 20. In this event, the contact points 310 of the terminals 30 come into contact with connection terminals (not shown) formed on the other of the principle surfaces of the card-type device 60 (a second principle surface). The supporting portions 312 of the terminals 30 support the contact points 310 to resist entering of the card-type device 60 into the accommodation portion 26. The supporting portions 312 are formed so that the locked portions 48 of the cover 40 are positioned upward of lower surfaces of the overhanging portions 224 of the front sidewalls 214 in the up-down direction when a force except for gravity is not applied on the connector 10 and the card-type device 60.

As shown in FIG. 5, upon further turning the cover 40 in the closing direction against reaction forces of the supporting portions 312 of the terminals 30, the locked portions 48 of the cover 40 are positioned downward of the locking portions 242 in the up-down direction. In this state, the cover 40 can move forward with respect to the base 20 and the card-type device 60. Upon sliding the cover 40 forward, the locked portions 48 of the cover 40 are positioned below the overhanging portions 224 of the front sidewalls 214 at least in part. When the push-down force to the cover 40 is removed, the connector 10 shifts into the locked state shown in FIG. 6.

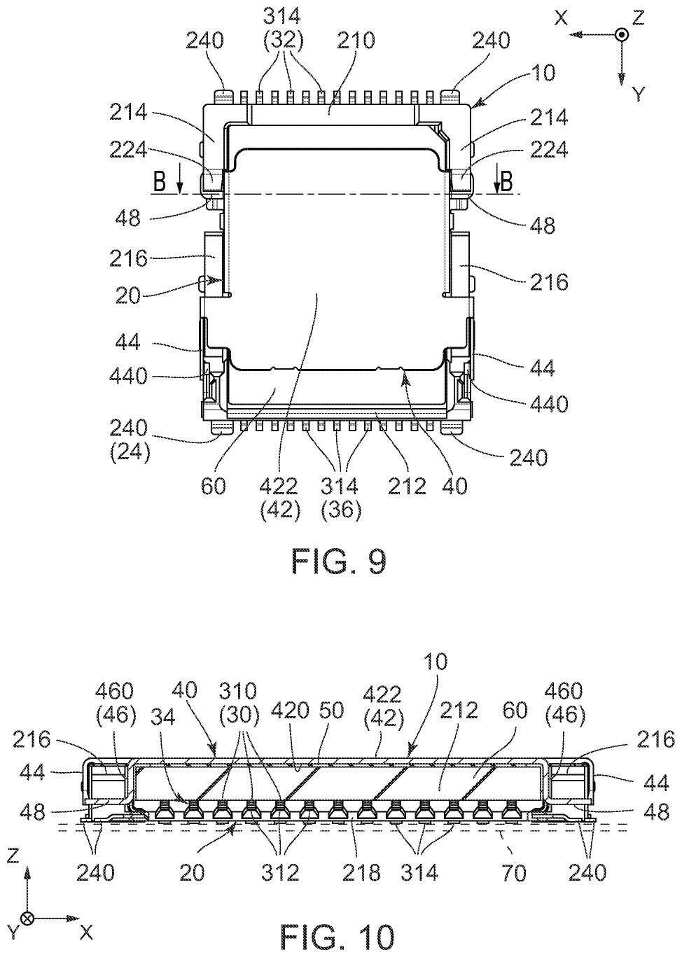

As understood from FIGS. 9 and 10, in the locked state, the terminals 30 apply an upward force on the card-type device 60 by the reaction forces of the supporting portions 312 of them. Accordingly, the card-type device 60 gives an upward force on the cover 40 via the heat conductive member 50.

As understood from FIG. 6, in the locked state, the locked portions 48 of the cover 40 are positioned below the overhanging portions 224 of the front sidewalls 214. Moreover, the axis portions 440 of the cover 40 are received by the bearing portions 226 at least in part. Accordingly, upward movement of the cover 40 is regulated when the cover 40 receives the upward force. In other words, when the connector 10 is connected to the card-type device 60, an interval between the main portion 42 of the cover 40 and each of the holding portions 210, 218 and 220 of the base 20 is kept constant in a predetermined direction perpendicular to the circuit board 70 (see FIG. 4). In the present embodiment, the predetermined direction coincides with the up-down direction.

As understood from FIG. 10, in the state that the interval between the main portion 42 of the cover 40 and each of the holding portions 210, 218 and 220 of the base 20 is kept constant, the card-type device 60 is pushed against the heat conductive member 50 by the reaction forces of the supporting portions 312 of the terminals 30. In other words, when the connector 10 is connected to the card-type device 60, the terminals 30 push the card-type device 60 against the heat conductive member 50 in the predetermined direction perpendicular to the circuit board 70. A direction of the force given from the terminals 30 to the card-type device 60 and a direction of a contact pressure working between the card-type device 60 and the heat conductive member 50 coincide with each other. Accordingly, the force given from the terminals 30 to the card-type device 60 becomes entirely a force pushing the first principle surface of the card-type device 60 against the heat conductive member 50. In this way, a high contact pressure is obtained between the heat conductive member 50 and the first principle surface of the card-type device 60. Thus, the card-type device 60 comes into surface contact with the heat conductive member 50, and heat generated in the card-type device 60 can be conducted to the cover 40 via the heat conductive member 50 with high heat conductive efficiency.

As mentioned above, the connector 10 according to the present embodiment can generate the high contact pressure between the heat conductive member 50 and the card-type device 60.

### Second Embodiment

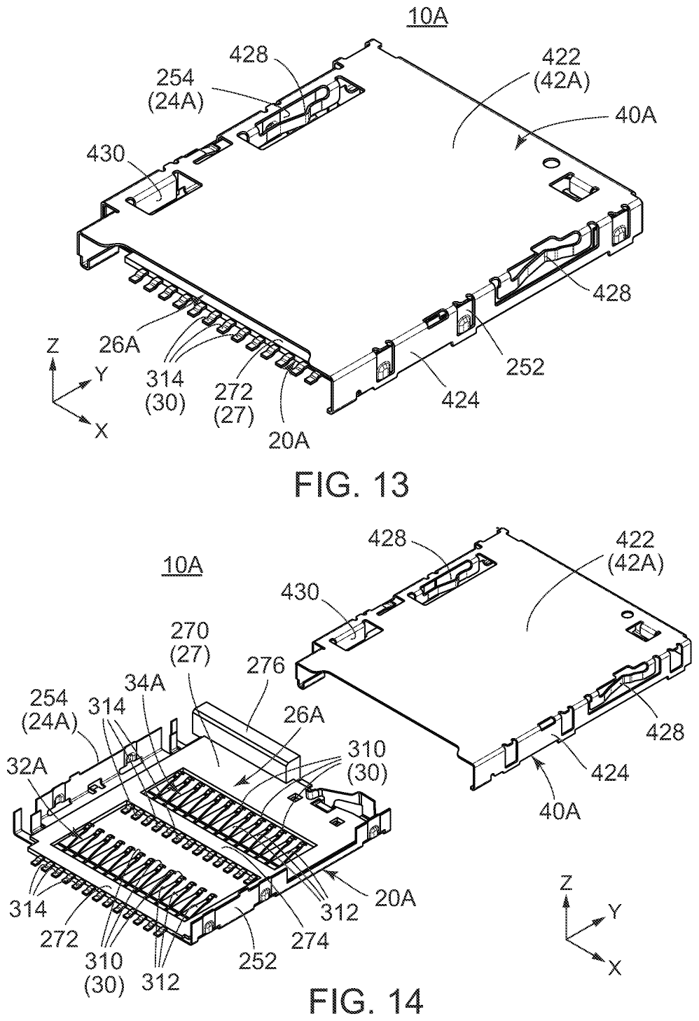

Referring to FIGS. 13 to 15, a connector 10A is provided with a base 20A, a plurality of terminals 30, a cover shell (a cover) 40A and a heat conductive member 50.

As understood from FIG. 16, the connector 10A of the present embodiment is also mounted on a circuit board 70 and connected to a card-type device 60 when used.

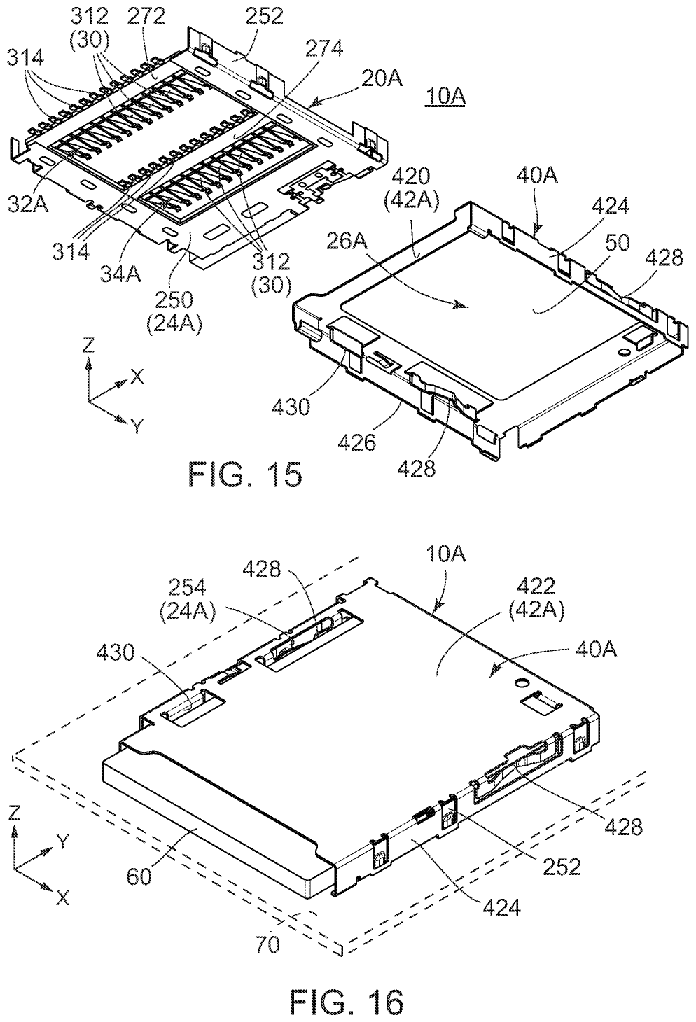

As understood from FIGS. 14 and 15, the base 20A consists of a frame 24A made of metal and a resin portion 27. The frame 24A is provided with a bottom plate 250 and a pair of side plates 252 and 254. The bottom plate 250 has an angular U-shape when viewed along the up-down direction. The side plates 252 and 254 protrude upward from both edges of the bottom plate 250 in the lateral direction and extend in the front-rear direction. The resin portion 27 has a bottom board portion 270 covering an upper surface of the bottom plate 250, two holding portions 272 and 274 extending in the lateral direction and holding the terminals 30 and a rear wall portion 276.

As shown in FIGS. 14 and 15, the terminals 30 are arranged in two rows and held by the holding portions 272 and 274 of the base 20A. In detail, the terminals 30 of a first terminal row 32A are held by the holding portions 272, and the terminals 30 of a second terminal row 34A are held by the holding portion 274.

As understood from FIGS. 14 and 15, the terminals 30 are formed similarly to the terminals 30 of the first embodiment. In other words, each of the terminals 30 has a contact point 310, a supporting portion 312, a held portion (not shown) and a fixed portion 314. In the present embodiment, the terminals 30 of the first terminal row 32A and the terminals 30 of the second terminal row 34 are formed to be identical to one another. However, the present invention is not limited thereto. The terminals 30 of the first terminal row 32A and the terminals 30 of the second terminal row 34A may be different from each other in size of each part, provided that they have the same basic structure as each other. In addition, the arrangement of the terminals 30 is not limited thereto but may be set freely.

As understood from FIGS. 14 and 15, the cover shell 40A is provided with a main portion 42A having a rectangular shape, a pair of side plates 424 and 426, a pair of holding springs 428 and an additional side plate 430. The main portion 42A of the cover shell 40A has an inner surface 420 directed downward in the up-down direction and an outer surface 422 directed upward in the up-down direction.

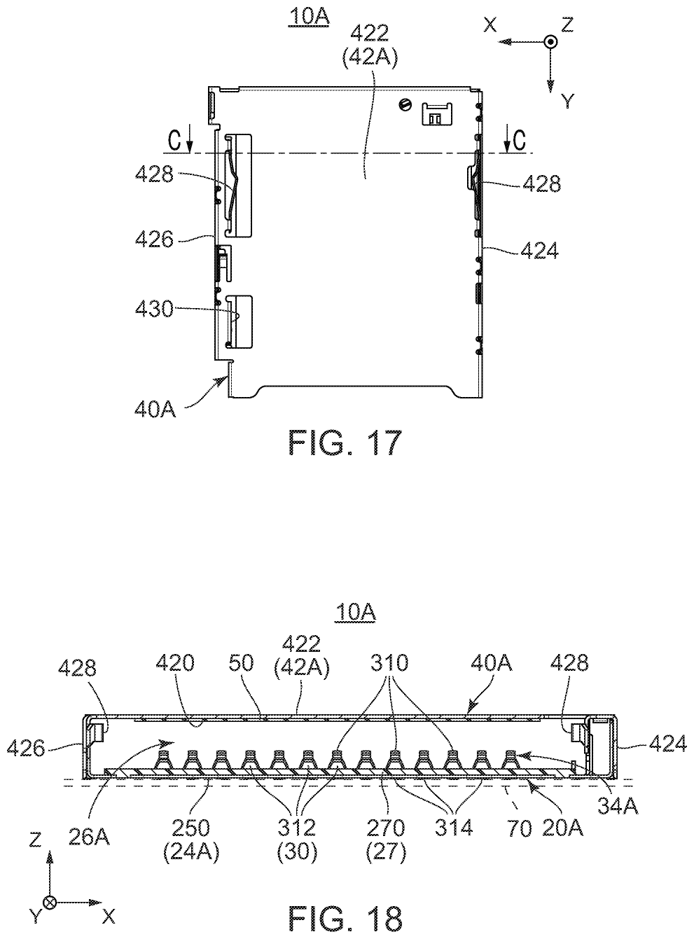

As understood from FIGS. 13, 17 and 18, the cover shell 40A is attached to the base 20A. In other words, the cover shell 40A and the base 20A are fixed to each other. In the present embodiment, the cover shell 40A and the base 20A are fixed to each other by snap-fitting. However, the present invention is not limited thereto. The cover shell 40A and the base 20A may be fixed to each other by a fixing method other than the snap-fitting.

As understood from FIG. 18, the cover shell 40A and the base 20A which are fixed to each other define an accommodation portion 26A which accommodates the card-type device 60 at least in part. When the cover shell 40A and the base 20A are fixed to each other, an interval between the main portion 42A and each of the holding portions 272 and 274 is kept constant in a predetermined direction perpendicular to the circuit board 70. In the present embodiment, the predetermined direction coincides with the up-down direction.

As shown in FIGS. 15 and 18, the heat conductive member 50 is fixed on the inner surface 420 of the main portion 42A of the cover shell 40A. In the present embodiment, the heat conductive member 50 is stuck on the inner surface 420 of the main portion 42A of the cover shell 40A. The heat conductive member 50 covers the most part of the inner surface 420 of the main portion 42A of the cover shell 40A. The heat conductive member 50 is formed similarly to the heat conductive member 50 of the first embodiment. In detail, the heat conductive member 50 is formed as shown in FIG. 11 or 12.

As understood from FIG. 18, the contact points 310 of the terminals 30 are supported the supporting portions 312 so as to be located in the accommodation portion 26A. The supporting portions 312 are resiliently deformable and support the contact points 310 to allow them to be moved at least in the up-down direction.

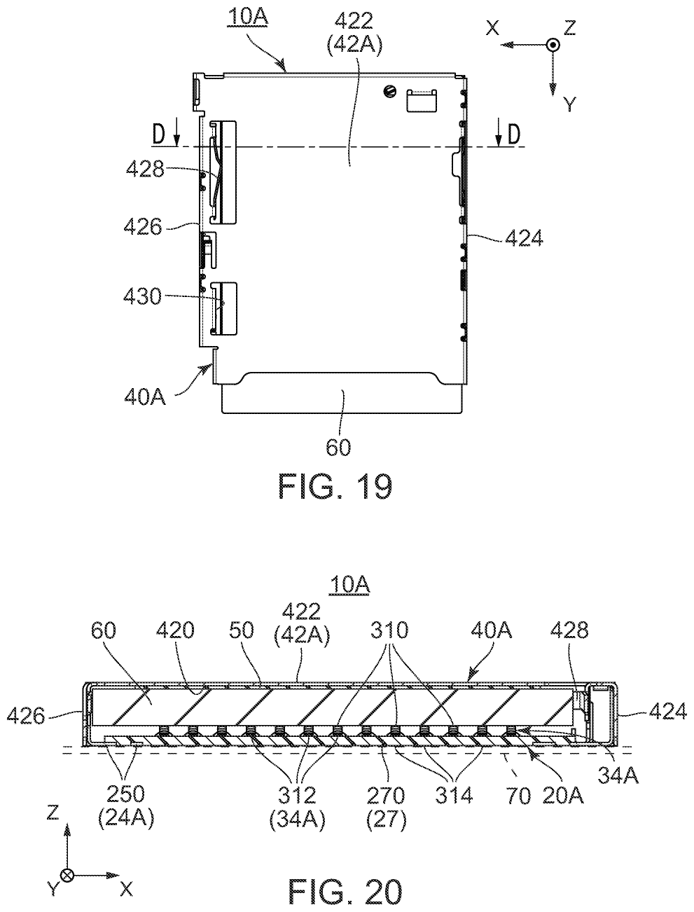

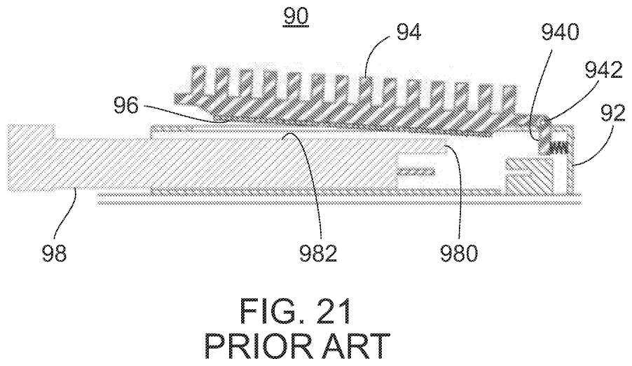

As understood from FIGS. 19 and 20, when the card-type device 60 is accommodated in the accommodation portion 26A, the contact points 310 of the terminals 30A come contact with connection terminals (not shown) formed on the second principle surface of the card-type device 60. In other words, the connector 10A is connected to the card-type device 60. In this event, the supporting portions 312 of the terminals 30A are resiliently deformed and push the contact points 310 against the card-type device 60 by reaction forces of them.

As understood from FIG. 20, when the card-type device 60 is accommodated in the accommodation portion 26A, the heat conductive member 50 faces the first principle surface of the card-type device 60. Accordingly, when the card-type device 60 receives the reaction forces of the supporting portions 312 via the contact points 310 of the terminals 30, the first principle surface of the card-type device 60 is pushed against the heat conductive member 50. In other words, when the connector 10A is connected to the card-type device 60, the terminals 30 push the card-type device 60 against the heat conductive member 50 in a predetermined direction perpendicular to the circuit board 70. In this event, a direction of the force given from the terminals 30 to the card-type device 60 and a direction of a contact pressure working between the first principle surface of the card-type device 60 and the heat conductive member 50 coincide with each other. Accordingly, the force given from the terminals 30 to the card-type device 60 becomes entirely a force pushing the first principle surface of the card-type device 60 against the heat conductive member 50. With this structure, the high contact pressure can be obtained between the heat conductive member 50 and the first principle of the card-type device 60. Thus, the card-type device 60 comes into surface contact with the heat conductive member 50, and heat generated in the card-type device 60 can be conducted to the cover shell 40A via the heat conductive member 50 with high heat conductive efficiency.

As mentioned above, also the connector 10A according to the present embodiment can generate the high contact pressure between the heat conductive member 50 and the card-type device 60.

Although the specific explanation about the present invention is made above referring to the embodiments, the present invention is not limited thereto but susceptible of various modifications and alternative forms without departing from the spirit of the invention. For example, although the heat conductive member 50 has the first heat conductive acrylic adhesive layer 502 in the aforementioned embodiments, a heat conductive adhesive agent may be used in place of it. Moreover, although each of the cover 40 and the cover shell 40A is made of a single metal plate in the aforementioned embodiments, it may be provided with a heat radiating member, such as a heatsink, on the outer surface 422. Furthermore, the base 20 may have a structure different from the aforementioned structure, provided that it has the holding portions 210, 218 and 220 holding the terminals 30. Similarly, the base shell 40 may have a structure different from the aforementioned structure, provide that it has the holding portions 272 and 274 holding the terminals 30.

While there has been described what is believed to be the preferred embodiment of the invention, those skilled in the art will recognize that other and further modifications may be made thereto without departing from the spirit of the invention, and it is intended to claim all such embodiments that fall within the true scope of the invention.

What is claimed is:

1. A connector connectable to a card-type device, wherein:
the connector is mounted on a circuit board when used;
the connector comprises a base, a terminal, a cover and a heat conductive member;
the base has a holding portion;
the terminal is held by the holding portion;
the cover comprises a main portion having an inner surface and an outer surface;
the heat conductive member is fixed on the inner surface;
when the connector is connected to the card-type device, the terminal pushes the card-type device against the heat conductive member in a predetermined direction perpendicular to the circuit board; and
when the connector is connected to the card-type device, an interval between the main portion and the holding portion is kept constant in the predetermined direction.

2. The connector as recited in claim 1, wherein the cover is attached to the base.

3. The connector as recited in claim 2, wherein the cover is attached to the base by means of a hinge mechanism.

4. The connector as recited in claim 1, wherein:
the heat conductive member has a covering layer made of polyimide;
in a state before the connector is connected to the card-type device, the card-type device is movable with respect to the cover; and
when the connector is connected to the card-type device, the covering layer faces the card-type device.
